(19) United States
(12) Patent Application Publication
(10) Pub. No.: US 2026/0182314 A1
(43) Pub. Date: Jun. 25, 2026

(54) TRENCHES AND METHOD FOR FABRICATING THE TRENCHES

(71) Applicant: HANGZHOU FULLSEMI SEMICONDUCTOR CO., LTD., Hangzhou (CN)

(72) Inventor: Yongjun NIU, Hangzhou (CN)

(73) Assignee: HANGZHOU FULLSEMI SEMICONDUCTOR CO., LTD., Hangzhou (CN)

(21) Appl. No.: 19/314,011

(22) Filed: Aug. 29, 2025

(30) Foreign Application Priority Data
Dec. 19, 2024 (CN) 2024118865599

(51) Int. Cl. H01L 21/033; H01L 21/306; H01L 21/308

(52) U.S. Cl. CPC H10P 76/4085; H10P 50/692; H10P 76/405; H10P 50/642

(57) ABSTRACT

Trenches and a method for fabricating the trenches. The method includes: forming a mask layer on a substrate; etching the mask layer to form a patterned mask layer, where the patterned mask layer exposes a portion of the substrate; removing a naturally-formed oxide layer on the exposed portion of the substrate, at which time a protective layer is formed at lower portions of sidewalls of the patterned mask layer; and etching the substrate using the patterned mask layer and the protective layer as a mask to form trenches in the substrate. The protective layer is formed before etching the substrate, and is used to protect the substrate so that the tops of trenches have a smooth topography.

### FIELD OF TECHNOLOGY

The present disclosure relates to semiconductor integrated circuits, in particular, to trenches and a method for fabricating the trenches.

### BACKGROUND

After a deep trench etching process, indentations will form at positions where the substrate and the mask layer contact at tops of the trenches, resulting in sharp corners (Notch) at tops of the trenches. During subsequent process steps, these sharp corners can easily degrade the isolation effect of the oxide layer in power device chips, leading to voltage breakdown and chip leakage.

FIG. 1 is a schematic enlarged cross-sectional view of a scanning electron microscope image of a structure after forming trenches in a substrate. Referring to FIG. 1, trenches 14 are formed in the substrate 10, and sharp corners exist at the tops of the trenches 14 (as indicated by the dashed circles).

The issue of sharp corners at tops of the trenches is generally addressed by adding a shallow trench etching step. However, this method also requires an additional photolithography step and an additional etching step, leading to increased costs. Alternatively, the issue of sharp corners at tops of the trenches can be addressed by adding a soft-etching step after trench etching. However, this method requires the purchase of specialized equipment tailored to the process, along with an additional mask cleaning process. Moreover, soft-etching currently lacks a mature and reliable process.

### SUMMARY

The present disclosure provides trenches and a method for fabricating the trenches, wherein before etching the substrate, a protective layer is formed on sidewalls of a patterned mask layer to protect the substrate beneath it, ensuring that the top of the formed trenches has a smooth morphology.

The method includes:
providing a substrate, and forming a mask layer on the substrate;
etching the mask layer to form a patterned mask layer, wherein the patterned mask layer exposes a portion of the substrate;
forming a protective layer at least at lower portions of sidewalls of the patterned mask layer when a naturally formed oxide layer on the exposed portion of the substrate is removed; and
etching the substrate using the patterned mask layer and the protective layer as a mask to form trenches in the substrate.

Optionally, forming the protective layer when the oxide layer is removed comprises: performing dry etching on the oxide layer using fluorocarbon gas, wherein during etching, a carbon-containing polymer protective layer is formed at least at lower portions of the sidewalls of the patterned mask layer.

Optionally, the protective layer is located on the sidewalls of the patterned mask layer, from a top to a bottom of the sidewalls, a width of the protective layer gradually increases.

Optionally, an atomic ratio of carbon to fluorine in the fluorocarbon gas is greater than 1:4.

Optionally, the fluorocarbon gas comprises CHF₃, CH₂F₂, or CH₃F.

Optionally, during the dry etching, a chamber pressure is 10 mtorr to 30 mtorr, an upper-electrode power is 600 W to 1000 W, a lower-electrode bias voltage is 100 V to 200 V, and a reaction time is 8 seconds to 30 seconds.

Optionally, etching the mask layer to form a patterned mask layer includes:
forming a photoresist layer on the mask layer;
exposing and developing the photoresist layer to form a patterned photoresist layer;
etching the mask layer using the patterned photoresist layer as a mask until the portion of the substrate is exposed; and
removing the patterned photoresist layer.

Optionally, the mask layer is over-etched until the mask layer is completely removed.

Optionally, a material of the mask layer includes silicon oxide, silicon nitride, or silicon oxynitride.

Optionally, after forming the trenches, the method further includes: removing the mask layer and the protective layer.

Accordingly, the present disclosure provides a semiconductor structure, the semiconductor structure is obtained by the methods described above, and the semiconductor structure includes:
a substrate;
a patterned mask layer located on the substrate;
a protective layer located at least at lower portions of the sidewalls of the patterned mask layer; and
trenches located in the substrate not covered by the patterned mask layer and the protective layer.

In the presently disclosed trenches and method for fabricating the trenches according to a protective layer is formed at least at lower portions of sidewalls of a patterned mask layer before etching the substrate, wherein the protective layer is used to protect the substrate beneath it, so that when the substrate is etched with the patterned mask layer as the mask to form trenches, the tops of the trenches have a smooth morphology. Furthermore, the protective layer is formed when a naturally formed oxide layer on the exposed portion of the substrate (i.e., during the Breakthrough step) is removed, with no additional specialized equipment or additional process steps required, thus saving fabrication costs.

### BRIEF DESCRIPTION OF THE DRAWINGS

FIG. 1 is an enlarged schematic diagram of a cross-section under a scanning electron microscope after a trench is formed in a substrate in the prior art.

FIGS. 2-7 are schematic structural diagrams of each step of a method for fabricating trenches.

FIG. 8 is a schematic flowchart illustrating a method for fabricating trenches according to one embodiment of the present disclosure.

FIGS. 9-11 are schematic structural diagrams of each step of a method for fabricating trenches according to one embodiment of the present disclosure.

FIG. 12 is an enlarged schematic diagram of a cross-section under a scanning electron microscope after a trench is formed in a substrate according to one embodiment of the present disclosure.

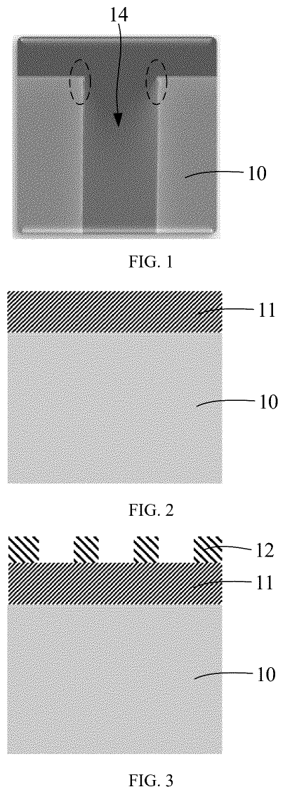

### REFERENCE NUMERALS

10 Substrate
11 Mask Layer
12 Patterned Photoresist Layer
13 Patterned Mask Layer
14 Trench
15 Protective Layer

### Detailed Description

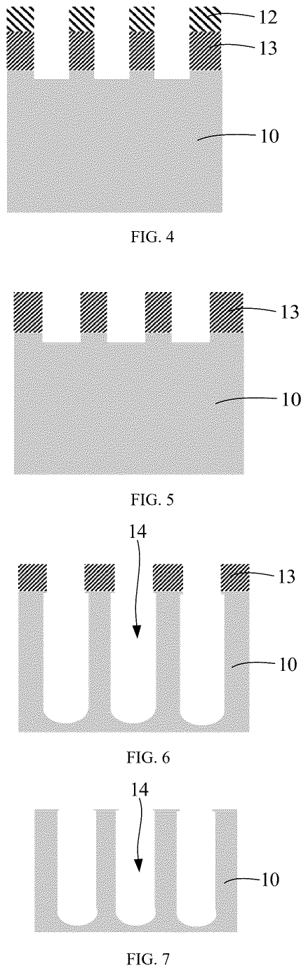

FIGS. 2-7 are schematic structural diagrams of each step of a method for fabricating trenches. Referring to FIGS. 2-7, the steps for forming trenches in a substrate typically include: first, forming a mask layer 11 on a substrate 10, resulting in the structure shown in FIG. 2; next, forming a photoresist layer on the mask layer 11, and exposing and developing the photoresist layer to form a patterned photoresist layer 12, wherein the patterned photoresist layer 12 exposes a portion of the mask layer 11, the exposed portion being located above a region of the substrate 10 predetermined for forming trenches, resulting in the structure shown in FIG. 3; then, referring to FIG. 4, etching the mask layer 11 using the patterned photoresist layer 12 as a mask to form a patterned mask layer 13, wherein the patterned mask layer 13 exposes a portion of the substrate 10, namely the region of the substrate 10 predetermined for forming trenches; subsequently, removing the patterned photoresist layer 12, at which point the exposed portion of the substrate 10 naturally oxidizes to form an oxide layer; etching the naturally formed oxide layer before etching the substrate 10, during which the BT (Breakthrough) step is performed; wherein a dry etching process using fluorocarbon gas, such as CF₄, is performed to remove the oxide layer, resulting in the structure shown in FIG. 5; thereafter, referring to FIG. 6, etching the substrate 10 using the patterned mask layer 13 as a mask to form trenches 14 in the substrate 10. Finally, referring to FIGS. 6-7, the patterned mask layer 13 is removed.

However, during the process of etching the substrate 10 to form the trenches 14, sharp corners are easily formed at the tops of the sidewalls of the trenches 14. As shown in FIG. 7, sharp corners are formed at the tops of the sidewalls of the trenches 14. And the sharp corners can easily cause device leakage in subsequent processes.

Therefore, it is necessary to round the sharp corners of the trenches 14. However, existing processes for addressing sharp corners at the tops of trenches require additional process steps and specialized equipment, leading to increased fabrication costs.

To address the above issues, the present disclosure provides trenches and a method for fabricating the trenches. In the presently disclosed method, after etching the mask layer to form a patterned mask layer that exposes a portion of the substrate, a protective layer is formed at least at lower portions of sidewalls of the patterned mask layer when a naturally formed oxide layer on the exposed portion of the substrate is removed (i.e., during the Breakthrough step, or BT step, before etching the substrate). The protective layer provides protection during trench etching, thereby forming trenches whose tops have a smooth topography.

Specifically, the method for fabricating trenches includes the following steps: providing a substrate and forming a mask layer on the substrate; etching the mask layer to form a patterned mask layer, wherein the patterned mask layer exposes a portion of the substrate; removing a naturally formed oxide layer on the exposed portion of the substrate, at which time a protective layer is formed at least at lower portions of sidewalls of the patterned mask layer; and etching the substrate using the patterned mask layer as a mask to form trenches in the substrate.

The present disclosure also provides a semiconductor structure, including: a substrate; a patterned mask layer located on the substrate; a protective layer located at least at lower portions of sidewalls of the patterned mask layer; and trenches located in the substrate not covered by the patterned mask layer and the protective layer.

The present disclosure forms a protective layer at least at lower portions of sidewalls of a patterned mask layer before etching the substrate, wherein the protective layer is used to protect the substrate beneath it, so that when the substrate is etched with the patterned mask layer as the mask to form trenches, the tops of the trenches have a smooth morphology. Furthermore, the present disclosure forms the protective layer when a naturally formed oxide layer on the exposed portion of the substrate (i.e., during the breakthrough step) is removed, without requiring additional specialized equipment or additional process steps, thus saving fabrication costs.

To make the objectives, advantages, and features of the present invention clearer, the present disclosure is further described in detail below with reference to the accompanying drawings and specific embodiments. It should be noted that the drawings are presented in a highly simplified form and are not necessarily drawn to scale, serving only to facilitate and clarify the explanation of the embodiments of the present disclosure. Additionally, the structures shown in the drawings often represent only a portion of the actual structure. In particular, different drawings may emphasize different aspects and may use different proportions.

As used in the present disclosure, the singular forms “a,” “an,” and “the” include plural referents unless the context clearly indicates otherwise. As used in the present disclosure, the term “or” is generally used in its inclusive sense of “and/or” unless the context clearly indicates otherwise. As used in the present disclosure, the term “several” is generally used to mean “at least one” unless the context clearly indicates otherwise. As used in the present disclosure, the term “at least two” is generally used to mean “two or more” unless the context clearly indicates otherwise. In addition, the terms like “first” and “second” are used for descriptive purpose only, and are not to be construed as indicating or implying relative importance or implicitly specifying numbers of technical features indicated. Thus, features qualified with terms like “first” and “second” may explicitly or implicitly include one or more such features.

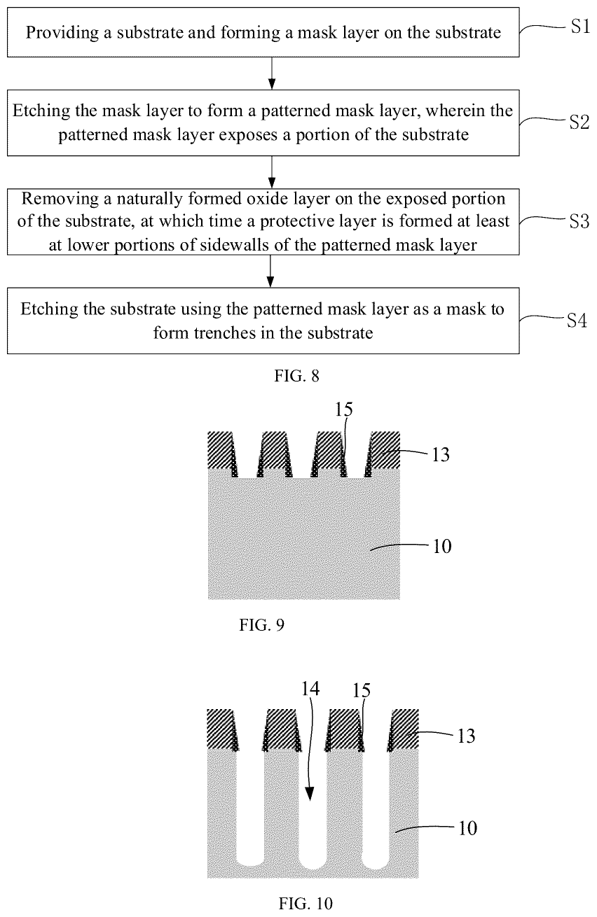

FIG. 8 is a schematic flowchart of a method for fabricating trenches according to one embodiment of the present disclosure. As shown in FIG. 8, the method for fabricating trenches includes following steps:
S1: providing a substrate and forming a mask layer on the substrate;
S2: etching the mask layer to form a patterned mask layer, wherein the patterned mask layer exposes a portion of the substrate;
S3: removing a naturally formed oxide layer on the exposed portion of the substrate at which time a protective layer is formed at least at lower portions of sidewalls of the patterned mask layer; and
S4: etching the substrate using the patterned mask layer as a mask to form trenches in the substrate.

FIGS. 9-11 are schematic structural diagrams of each step of a method for fabricating trenches according to one embodiment of the present disclosure. Next, the method for fabricating trenches according to an embodiment of the present disclosure will be described in detail with reference to FIG. 8, FIGS. 2-4, and FIGS. 9-11.

In S1, referring to FIG. 2, the substrate 10 is provided, and a mask layer 11 is formed on the substrate 10.

In some embodiments, the material of the substrate 10 may include silicon, germanium, silicon germanium, silicon carbide, gallium arsenide, or indium gallium, or may be silicon-on-insulator or germanium-on-insulator; alternatively, the material of the substrate 10 may include other materials, such as III-V compound semiconductors like gallium arsenide. In this embodiment, the substrate 10 is a silicon substrate.

The material of the mask layer 11 may include silicon oxide, silicon nitride, or silicon oxynitride, or may include any other suitable materials known to those skilled in the art. The mask layer 11 may be a single-layer structure or a stacked structure including two or more layers. In one embodiment, the mask layer 11 is a single-layer structure including silicon oxide. The mask layer 11 may be formed using any suitable process known to those skilled in the art, such as atomic layer deposition, chemical vapor deposition, or physical vapor deposition.

In S2, referring to FIG. 4, the mask layer 11 is etched to form a patterned mask layer 13, wherein the patterned mask layer 13 exposes a portion of the substrate 10.

In one embodiment of the present disclosure, the method for etching the mask layer 11 to form a patterned mask layer 13 may include: first, forming a photoresist layer (not shown) on the mask layer 11; then, referring to FIG. 3, exposing and developing the photoresist layer to form the patterned photoresist layer 12, wherein the patterned photoresist layer 12 exposes a portion of the mask layer 11, and the projection of the exposed portion on the substrate 10 coincides with a region of the substrate 10 predetermined for forming trenches; subsequently, etching the mask layer 11 using the patterned photoresist layer 12 as a mask until a portion of the substrate 10 is exposed, resulting in the structure shown in FIG. 4; thereafter, removing the patterned photoresist layer 12, for example, using an ashing process or a wet etching process to remove the patterned photoresist layer 12.

For example, a dry etching process may be used to etch the mask layer 11, and the etching gas may include fluorocarbon gas such as CF₄ or CHF₃. In one embodiment of the present disclosure, the mask layer 11 is over-etched until the mask layer 11 is completely removed, as shown in FIG. 4. When the mask layer 11 is over-etched, the exposed portion of the substrate 10 is slightly etched. That is, after etching the mask layer 11 to form the patterned mask layer 13, a recess exposing a portion of the substrate 10 is formed within the patterned mask layer 13, with the bottom of the recess located within the substrate 10.

In S3, referring to FIG. 9, a naturally formed oxide layer on the exposed portion of the substrate 10 is removed, at which time a protective layer 15 is formed at least at lower portions of sidewalls of the patterned mask layer 13.

After forming the patterned mask layer 13, S3 exposes a portion of the substrate 10, the surface of the exposed portion of the substrate 10 is naturally oxidized to form an oxide layer. This oxide layer needs to be removed before etching the substrate 10, i.e., performing a BT step to remove the naturally formed oxide layer. In one embodiment, during the BT step, a protective layer 15 is formed at least at lower portions of sidewalls of the patterned mask layer 13.

In one embodiment of the present disclosure, a dry etching process using fluorocarbon gas is performed to etch the oxide layer, and during the etching process, a carbon-containing polymer protective layer is formed at least at lower portions of sidewalls of the patterned mask layer 13. Compared to performing only the BT step, in the presently disclosed dry etching process the carbon content in the fluorocarbon gas is appropriately higher, to facilitate forming a carbon-containing polymer protective layer on the sidewalls of the patterned mask layer 13. For example, an atomic ratio of carbon to fluorine in the fluorocarbon gas is greater than 1:4, meaning that, compared to the BT step using CF₄, the carbon content in the dry etching process using fluorocarbon gas is higher, facilitating the deposition of a carbon-containing polymer on the sidewalls of the patterned mask layer 13. In one embodiment, the fluorocarbon gas includes gases with relatively high carbon content, such as CHF₃, CH₂F₂, or CH₃F.

In one embodiment of the present disclosure, the protective layer 15 covers entire sidewalls of the patterned mask layer 13, and from the top to the bottom of the sidewalls, the width of the protective layer 15 (i.e., the thickness in the horizontal direction as shown in FIG. 9) gradually increases. Referring to FIG. 9, a cross-sectional profile of the protective layer 15 is triangular. The shape and width of the protective layer 15 may be determined by the specific etching gas (e.g., the carbon content in the etching gas) and the duration of the etching process. The protective layer 15 initially accumulates at the bottom of the sidewalls of the patterned mask layer 13 (i.e., the sidewalls of the recess within the patterned mask layer 13). As the etching progresses, the protective layer 15 continues accumulation, extending from the bottom to the top of the sidewalls.

In one embodiment of the present disclosure, during the dry etching process, a chamber pressure may range from 10 mtorr to 30 mtorr, an upper electrode power may range from 600 W to 1000 W, a lower electrode bias voltage may range from 100 V to 200 V, and a reaction time may range from 8 seconds to 30 seconds. For example, the chamber pressure may be, for example, 10 mtorr, 15 mtorr, 20 mtorr, 25 mtorr, or 30 mtorr, with a preferred chamber pressure of 20 mtorr; the upper electrode power may be, for example, 600 W, 700 W, 800 W, 900 W, or 1000 W, with a preferred upper electrode power of 800 W; the lower electrode bias voltage may be, for example, 100 V, 150 V, or 200 V, with a preferred lower electrode bias voltage of 150 V; the reaction time may be, for example, 8 seconds, 10 seconds, 15 seconds, 20 seconds, 25 seconds, or 30 seconds, with a preferred reaction time of 20 seconds. A longer reaction time results in a thicker carbon-containing polymer protective layer, and the reaction time can be adjusted based on actual requirements. The upper electrode power is used to promote gas dissociation producing plasma, while the lower electrode bias voltage directs the plasma to bombard the substrate. The specific value of each process parameter can be determined based on actual requirements.

In one embodiment, referring to FIG. 9, the protective layer 15 covers a portion of the substrate 10, enabling protection of the substrate 10 beneath it during subsequent etching, thereby forming trenches whose tops have a smooth topography.

In one embodiment of the present disclosure, the protective layer 15 may be formed before the BT step. For example, after forming the patterned mask layer 13, the protective layer 15 is formed on the sidewalls of the patterned mask layer 13. For example, fluorocarbon gases such as C₄F₈ or C₄F₆ may be used to form a carbon-containing polymer protective layer on the sidewalls through a deposition process. After forming the protective layer 15, the BT step is performed to remove the naturally formed oxide layer on the substrate 10. Additionally, since the BT step etches the oxide layer after the formation of the protective layer 15, the protective layer 15 may be etched during the BT step. Therefore, when forming the protective layer 15, its thickness should be appropriately increased to prevent complete removal during the BT step.

In S4, referring to FIG. 10, the substrate 10 is etched using the patterned mask layer 13 and the protective layer 15 as a mask, forming the trenches 14 in the substrate 10.

In one embodiment, a dry etching process may be used to etch the substrate 10. The etching gas may, for example, include a mixed gas comprising chlorine (CL₂) and hydrogen bromide (HBr), or a mixed gas comprising sulfur hexafluoride (SF₆) and oxygen (O₂). Alternatively, other gases known to those skilled in the art for etching semiconductor substrates may also be used. In one embodiment, sulfur hexafluoride (SF₆) and oxygen (O₂) are used as the etching gas to etch the substrate 10.

Due to the protection provided by the protective layer 15, when the substrate 10 is etched using the patterned mask layer 13 as a mask to form the trenches 14, thereby forming trenches 14 whose tops have a smooth topography.

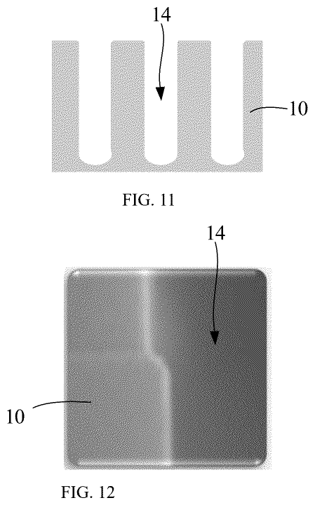

FIG. 12 is an enlarged schematic diagram of a cross-section under a scanning electron microscope after a trench is formed in a substrate according to one embodiment of the present disclosure. As shown in FIG. 12, the top of the trench 14 fabricated using the method for fabricating trenches described in the present disclosure has a smooth topography.

After forming the trenches 14, the method further includes removing the patterned mask layer 13 and the protective layer 15. Referring to FIGS. 10-11, the patterned mask layer 13 and the protective layer 15 are removed. For example, a wet etching process may be used to remove the patterned mask layer 13 and the protective layer 15. The etchant used in the wet etching process may be diluted hydrofluoric acid (HF). Alternatively, other etchants may be used, such as an EKC solution (the active component of the EKC solution is hydroxylamine hydrochloride, or hydroxylamine and ammonia, or a solution containing-NH2-OH groups), or a BOE solution (a mixture of 49% hydrofluoric acid aqueous solution and ammonium fluoride aqueous solution in a specific ratio). Additionally, other etchants known to those skilled in the art may also be used.

Due to the protective layer 15 being formed simultaneously with the removal of the naturally formed oxide layer on the substrate 10, and the protective layer 15 being removed simultaneously with the removal of the patterned mask layer 13, the formation and removal of the protective layer 15 do not require additional process steps or specialized equipment. Compared to methods in the prior art for addressing sharp corners at the tops of trenches, the presently disclosed approach saves fabrication costs.

Accordingly, the present disclosure provides a semiconductor structure, wherein the semiconductor structure may or may not be obtained by the methods described above. Referring to FIG. 10, the semiconductor structure includes:
the substrate 10;
the patterned mask layer 13 located above the substrate 10;
the protective layer 15 located at least at lower portions of the sidewalls of the patterned mask layer; and
trenches 14 located in regions of the substrate 10 not covered by the patterned mask layer 13 and the protective layer 15.

In one embodiment of the present disclosure, the protective layer 15 is a carbon-containing polymer protective layer.

In one embodiment of the present disclosure, the protective layer 15 is located on the entire sidewalls of the patterned mask layer 13, and from the top to the bottom of the sidewalls, a width of the protective layer 15 (i.e., the thickness in the horizontal direction as shown in FIG. 10) gradually increases. For example, a cross-sectional profile of the protective layer 15 is triangular.

In one embodiment of the present disclosure, due to the protection according to the protective layer 15, each of the formed trenches 14 have a smooth topography at their tops.

In summary, in the trenches and the method for fabricating the trenches according to the present disclosure, the method includes the following steps: first, providing a substrate and forming a mask layer on the substrate; then, etching the mask layer to form a patterned mask layer, where the patterned mask layer exposes a portion of the substrate; subsequently, removing a naturally formed oxide layer on the exposed portion of the substrate, at which time a protective layer is formed at least at lower portions of sidewalls of the patterned mask layer; and then, etching the substrate using the patterned mask layer as a mask to form trenches in the substrate. The present disclosure forms a protective layer at least at lower portions of sidewalls of a patterned mask layer before etching the substrate, where the protective layer is used to protect the substrate beneath it, so that when the substrate is etched with the patterned mask layer as the mask to form trenches, the tops of the trenches have a smooth morphology. Furthermore, in the present disclosure, the protective layer is formed when a naturally formed oxide layer on the exposed portion of the substrate (i.e., during the Breakthrough step) is removed, without requiring additional specialized equipment or additional process steps, thus saving fabrication costs.

The above description is merely illustrative of preferred embodiments of the present disclosure and is not intended to limit the scope of the present disclosure. Any changes or modifications made by those skilled in the art based on the above disclosure fall within the protection scope of the claims.

What is claimed is:

1. A method for fabricating trenches, comprising;
providing a substrate, and forming a mask layer on the substrate;
etching the mask layer to form a patterned mask layer, wherein the patterned mask layer exposes a portion of the substrate;
removing a naturally formed oxide layer on the exposed portion of the substrate, at which time a protective layer is formed at least at lower portions of sidewalls of the patterned mask layer; and
etching the substrate using the patterned mask layer and the protective layer as a mask to form trenches in the substrate.

2. The method for fabricating trenches according to claim 1, wherein forming the protective layer when the naturally formed oxide layer is removed comprises:
performing dry etching on the oxide layer using fluorocarbon gas, wherein during etching, a carbon-containing polymer protective layer is formed at least at lower portions of the sidewalls of the patterned mask layer.

3. The method for fabricating trenches according to claim 2, wherein the protective layer is located on the sidewalls of the patterned mask layer, from a top to a bottom of the sidewalls, a width of the protective layer gradually increases.

4. The method for fabricating trenches according to claim 2, wherein an atomic ratio of carbon to fluorine in the fluorocarbon gas is greater than 1:4.

5. The method for fabricating trenches according to claim 4, wherein the fluorocarbon gas comprises CHF₃, CH₂F₂, or CH₃F.

6. The method for fabricating trenches according to claim 5, wherein during the dry etching, a chamber pressure is 10 mtorr to 30 mtorr, an upper-electrode power is 600 W to 1000 W, a lower-electrode bias voltage is 100 V to 200 V, and a reaction time is 8 seconds to 30 seconds.

7. The method for fabricating trenches according to claim 1, wherein etching the mask
layer to form a patterned mask layer comprises:
forming a photoresist layer on the mask layer;
exposing and developing the photoresist layer to form a patterned photoresist layer;
etching the mask layer using the patterned photoresist layer as a mask until the portion of the substrate is exposed; and
removing the patterned photoresist layer.

8. The method for fabricating trenches according to claim 7, wherein the mask layer is over-etched until the mask layer is completely removed.

9. The method for fabricating trenches according to claim 1, wherein a material of the mask layer comprises silicon oxide, silicon nitride, or silicon oxynitride.

10. The method for fabricating trenches according to claim 1, wherein after forming the trenches, the method further comprises: removing the mask layer and the protective layer.

11. A semiconductor structure comprising trenches, wherein the semiconductor structure is obtained by the method according to claim 1.
